(19) United States
(12) Patent Application Publication
(10) Pub. No.: US 2007/0008770 A1
(43) Pub. Date: Jan. 11, 2007

(54) STORAGE DEVICES AND SEMICONDUCTOR DEVICES

(76) Inventors: Hajime Nagao, Nagasaki (JP); Hidenari Hachino, Nagasaki (JP); Hironobu Mori, Nagasaki (JP); Chieko Fukumoto, Nagasaki (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(21) Appl. No.: 11/428,023

(22) Filed: Jun. 30, 2006

(30) Foreign Application Priority Data
Jul. 8, 2005 (JP) P2005-199799

(51) Int. Cl. G11C 11/00; G11C 7/06; G11C 7/00

(52) U.S. Cl. 365/148; 365/218; 365/189.07

(57) ABSTRACT

The present invention provides a storage device including a storage element, a circuit element, and write control means. The storage element has a characteristic exhibiting a resistance changing from a large value to a small value due to application of an electrical signal at least equal to a first threshold signal but changing from a small value to a large value due to application of an electrical signal at least equal to a second threshold signal. The circuit element is connected in series to the storage element. The write control means is configured to carry out a first write operation, detect a resistance by the storage element after an n-th write operation, where n≧1, compare the detected resistance with the set value, and carry out a (n+1)-th write operation.

### CROSS REFERENCE TO RELATED APPLICATION

The present invention contains subject matter related to Japanese Patent Application JP 2005-199799 filed in the Japanese Patent Office on Jul. 8, 2005, the entire contents of which being incorporated herein by reference.

### BACKGROUND OF THE INVENTION

1. Field of the Invention

The present invention relates to a storage device and a semiconductor device. To put it in more detail, the present invention relates to storage and semiconductor devices, which include memory cells each using a storage element for storing and holding information in accordance with the electrical-resistance state of the storage element.

2. Description of the Related Art

In apparatus such as a computer, a DRAM (Dynamic Random-Access Memory) having a high operating speed and a high information storage density is employed as a random-access memory.

Because the DRAM is a volatile memory, which unavoidably loses information stored therein when the power supply thereof is turned off, a nonvolatile memory without losing information stored therein is desired.

In response to the demand for such a desired nonvolatile memory, a memory of a variable type has been proposed. Examples of the memory having a bright prospect are an FeRAM (ferro-dielectric RAM), an MRAM (magnetic memory), a phase-change memory, a PMC (Programmable Metallization Cell), and an RRAM (Resistance RAM).

The above memories are each capable of continuously holding information written thereto even without supplied power. In addition, since these memories are nonvolatile, a refresh operation is not necessary, allowing the power consumption to be reduced by a magnitude equivalent to an amount of power for the refresh operation.

In addition, the nonvolatile memory such as the PMC and the RRAM has a relatively simple configuration in which a material having a characteristic of exhibiting a variable resistance caused by application of a voltage or a current is used on a storage layer for storing and holding information, and the storage layer is sandwiched by two electrodes for receiving the applied voltage or current. Thus, the relatively simple configuration simplifies the miniaturization of the storage element.

It is to be noted that, in particular, the PMC has a structure in which the two electrodes sandwich an ion conductor including a predetermined metal. In addition, by including the metal of the ion conductor also in one of the two electrodes, it is possible to make use of a variable electrical characteristic caused by a voltage applied between the two electrodes. Examples of the variable electrical characteristic are a variable resistance and a variable capacitance.

To put it concretely, the ion conductor is composed of a chalcogenite material and a metallic solid solution such as an amorphous GeS or amorphous GeSe solid solution. One of the two electrodes includes Ag, Cu, or Zn. For more information on this, refer to documents such as JP-A-2002-536840 (Patent Document 1).

In an introduced configuration of the RRAM, the two electrodes sandwich a polycrystalline PrCaMnO₃ thin film. By applying voltage pulses between the two electrodes or flowing current pulses between the electrodes, the resistance of the polycrystalline PrCaMnO₃ thin film changes much. For more information on this configuration, refer to documents such as W. W. Zhuang et al., ‘Novel Colossal Magnetoresistive Thin Film Nonvolatile Resistance Random Access Memory (RRAM),’ Technical Digest “International Electron Devices Meeting,” 2002, page 193 (Non-patent Document 1). The polarity of a voltage pulse applied in a recording (write) operation is opposite to the polarity of a voltage pulse applied in an erase operation.

In another introduced configuration of the RRAM, typically, two electrodes sandwich a polycrystalline or monocrystalline SrZrO₃ recording film doped with little Cr and, by flowing a current from the electrodes, the resistance of the recording film changes. For more information on this configuration, refer to documents such as A. Beck et al., ‘Reproducible switching effect in thin oxide films for memory applications,’ Applied Physics Letters, 2000, Vol. 77, pages 139-141 (Non-patent Document 2).

The document shows the I-V characteristic of the storage layer. The values of a voltage applied in recording and erase operations are ±0.5 V. Also in this configuration, by applying a pulse voltage to the electrodes, information can be recorded onto the recording layer or erased from it. In this case, the pulse voltage has values of ±1.1 V, and the pulse width is 2 ms. Further, it is possible to record or erase information at high speeds. An operation by applying a pulse having a width of 100 ns has been reported. In this case, the necessary pulse voltages are ±0.5 V.

In the case of the FeRAM, on the other hand, it is difficult to carry out a non-destructive read operation. Since the read operation is destructive, the read operation is slow. In addition, since there is a limit of the number of polarity inversions caused by read and write operations, the number of operations that can be carried out to rewrite information already stored in the FeRAM is also limited.

In the case of the MRAM, a magnetic field is necessary for recording operations. Thus, since the magnetic field is generated flowing a current along a wire, a large current is consumed during a recording operation.

In the case of the phase-change memory, a recording operation is carried out by applying pulses having the same polarity but having different magnitudes. However, the phase-change memory has problems that the memory trips due to humidity and the memory is sensitive to changes in ambient temperature.

In the case of the PMC disclosed in patent document 1, the crystallization temperature of the amorphous GeS and amorphous GeSe solid solutions is approximately 200 degrees Celsius and, if the ion conductor is crystallized, the characteristic deteriorates. Thus, in actuality, the PMC has a problem that it is difficult to endure a high temperature generated in a process to create a storage element. A typical process to create a storage element is a process to form films such as a CVD insulation film or a protection film.

The material of a recording layer proposed in the configuration of the RRAM disclosed in non-patent documents 1 and 2 is a material having a crystalline characteristic in either case. Thus, the RRAM has a problem that the necessity to carry out processing at about 600 degrees Celsius and fabrication of mono crystals of the proposed material are both extremely difficult things. In addition, the RRAM also has a problem that miniaturization is difficult due to a grain-boundary effect, which is generated when poly crystals are used.

In addition, in the case of the RRAM, a there has been proposed a configuration in which information is recorded into the RRAM or erased from the RRAM by applying a pulse voltage. In the proposed configuration, however, the resistance of the post-recording layer unavoidably changes in dependence on the width of the applied pulse voltage. The fact that the resistance of the post-recording layer depends on the width of the applied pulse voltage in this way implicitly indicates that the resistance changes even if the same pulse is applied repeatedly.

For example, non-patent document 1 cited above describes a phenomenon in which, if pulses having the same polarity are applied, the resistance of the post-recording layer changes much in dependence on the pulse width. In the case of a small pulse width not exceeding 50 ns, the resistance change rate caused by recording is also small. In the case of a large pulse width of at least 100 ns, on the other hand, the RRAM exhibits a characteristic that, as the pulse width increases, the post-recording resistance adversely approaches the pre-recording resistance instead of getting saturated at a constant value. In addition, non-patent document 1 also introduces a characteristic of a memory structure implemented as an array of memory cells each having a storage layer and a MOS transistor connected in series to the storage layer as a transistor used for control of accesses to the storage layer. The reference also discloses the fact that, in this case, when the pulse width is changed in the range 10 ns to 100 ns, the post-recording resistance of the storage layer varies in dependence on the pulse width. If the pulse width is further increased, it is expected that, in accordance with the characteristic of the storage layer, the resistance again decreases.

That is to say, in the case of the RRAM, the post-recording resistance depends on the magnitude and width of the pulse voltage. Thus, if there are variations in pulse-voltage magnitude and pulse-voltage width, variations in post-recording resistance are also generated.

Accordingly, in the case of pulse voltages having small widths not exceeding a value of about 100 ns, the resistance change rate caused by a recording operation is small, being prone to effects of variations in post-recording resistance. As a result, there is raised a problem of difficulties to carry out a stable recording operation.

In order to solve the above problem, when a recording operation is carried out by using a pulse voltage having a small width, it is necessary to carry out a process of confirming (or verifying) information stored during the recording operation.

For example, prior to a recording operation, a process to read out and verify the contents of information already recorded in a storage element is carried out and a recording operation is carried out for a relation between the verified contents and contents being recorded. In this case, by the contents of information already recorded in a storage element or to be recorded into a storage element, the resistance of the storage element is meant. As an alternative, for example, right after a recording operation, a process to read out and verify the contents of information recorded in a storage element is carried out and, if the resistance representing the contents of information recorded in the storage element is different from those of information corresponding to a desired resistance, a re-recording process is performed in order to correct the resistance representing the contents of information recorded in the storage element to the desired resistance.

Thus, it takes long time to carry out a recording operation. In addition, it is difficult for example to carry out a write operation by superposition of data at a high speed.

In order to solve the problems described above, there is proposed a storage device including a plurality of memory cells. Each of the memory cells is designed into a configuration including a storage element, which has a characteristic exhibiting a resistance changing due to a threshold-exceeding voltage applied between its terminals, and a MOS transistor connected in series to the storage element as a load borne by the storage element. The storage device has characteristic that, when a voltage applied between the two terminals of a series circuit composed of the storage element and the MOS transistor exceeds a threshold value, a compound resistance, which is displayed by the storage element and MOS transistor included in the memory cell right after the resistance of the storage element has changed from a large value to a small value, becomes all but a constant independently of the magnitude of the applied voltage. For more information on such a storage device, refer to documents such as Japanese Patent Application 2004-22121 (Patent Document 2). By using this storage device, it is possible to implement stable information-recording operations and shorten the time it takes to carry out each of the information-recording operations.

### SUMMARY OF THE INVENTION

An operation to change the resistance of a storage element from a large value to a small value is defined as a write operation whereas an operation to change the resistance of a storage element from a small value to a large value is defined as an erase operation. The resistance exhibited by a storage element right after a write operation is determined by a current flowing through the storage element, and the magnitude of the current flowing through the storage element is affected by the on-resistance of the MOS transistor connected in series to the storage element. Since the on-resistance of the MOS transistor is not fixed due to variations of a process to manufacture the MOS transistor, there are also variations in storage-element characteristic. It is thus difficult to make the resistance exhibited by a storage element right after a write operation uniform among memory cells.

It is to be noted that, if the resistance exhibited by a storage element right after a write operation does not become a set value determined in advance, that is, if a write operation ends in a failure, a write operation is carried out again after erasing information from the storage element. In this way, it is possible to implement a write operation on a storage element as an operation that results in a storage-element resistance equal to the set value. If an erase operation needs to be performed on a storage element in case a write operation carried out on the storage element ends in a failure, however, a sequence for the erase operation is necessary. Thus, it takes long time to carry out a write operation. As a result, it is difficult to state that this technique is certainly a proper method.

In order to solve the problems described above, inventors of the present invention have proposed a storage device and a semiconductor device capable of reducing variations of the resistance exhibited by every storage element employed in the storage device right after a write operation among memory cells.

In order to realize the storage device as described above, the storage device is configured so as to include memory cells. Each memory cell is implemented by a storage element and a circuit element connected in series to the storage element having a characteristic exhibiting a resistance thereof changing from a large value to a small value due to application of an electrical signal at least equal to a first threshold signal. However, the storage element changes its resistance from a small value to a large value due to application of an electrical signal at least equal to a second threshold signal having a polarity opposite to that of the first threshold signal. The storage device also includes write control means configured to carry out a first write operation in an attempt to set the storage element to a higher resistance than a set value determined in advance, detect a resistance exhibited by the storage element right after the n-th write operation, where n≧1, compare the detected resistance with the set value, and carry out a (n+1)-th write operation if a result of comparison indicates that the resistance exhibited by the storage element right after the n-th write operation is still greater than the set value.

In order to realize the semiconductor device as described above, the semiconductor device is configured to have a storage device configured to include memory cells. Each memory cell is implemented by a storage element and a circuit element connected in series to the storage element having a characteristic exhibiting a resistance thereof changing from a large value to a small value due to application of an electrical signal at least equal to a first threshold signal. However, the storage element changes its resistance from a small value to a large value due to application of an electrical signal at least equal to a second threshold signal having a polarity opposite to that of the first threshold signal. The semiconductor device includes write control means configured to carry out a first write operation in an attempt to set the storage element to a higher resistance than a set value determined in advance, detect a resistance exhibited by the storage element right after the n-th write operation, where n≧1, compare the detected resistance with the set value, and carry out a (n+1)-th write operation if a result of comparison indicates that the resistance exhibited by the storage element right after the n-th write operation is still greater than the set value.

As described above, the write control means is configured so as to carry out a first write operation in an attempt to set the storage element to a higher resistance than a set value determined in advance, detect a resistance exhibited by the storage element right after the n-th write operation, where n≧1, compare the detected resistance with the set value, and carry out a (n+1)-th write operation if a result of comparison indicates that the resistance exhibited by the storage element right after the n-th write operation is still greater than the set value. That is to say, by carrying out an overwrite (or rewrite) operation on a storage element once completing a write operation and, if necessary, write as well as read operations carried out thereon a plurality of times repeatedly, it is possible to perform write operations in an attempt to set the resistance of the storage element to be a set value determined in advance.

After a storage element has been put in a conductive state by carrying out a write operation once on the storage element, the resistance of the storage element will not increase even if a rewrite operation is carried out on the storage element by flowing a current smaller than a current flown in the first write operation to the storage element. If rewrite operation is carried out on the storage element flowing a current greater than a current flown in the first write operation to the storage element, on the other hand, the resistance of the storage element decreases. That is to say, if the resistance exhibited by the storage element right after a write operation is smaller than the set value, the resistance of the storage element is difficult to be increased to the set value even if a rewrite operation is carried out on the storage element.

Thus, in accordance with an embodiment of the present invention, a first write operation is carried out on a storage element in an attempt to set the resistance of the storage element to a value equal to the set value determined in advance so that, by carrying out second and subsequent overwrite (or rewrite) operations on the storage element if necessary, the storage element becomes a higher resistance than the set value.

In the storage and semiconductor devices provided by an embodiment of the present invention as described above, a write operation is carried out on each storage element to make the storage element equal to a set value determined in advance so that variations in storage-element resistance among storage elements (or memory elements) can be reduced.

### BRIEF DESCRIPTION OF THE DRAWINGS

FIG. 1 is a diagram showing a graph representing an I-V relation between changes in current and changes in voltage for a memory element used in a typical storage device according to an embodiment of the present invention;

FIGS. 2A and 2B are explanatory diagrams showing circuits of a memory cell used in the typical storage device according to an embodiment of the present invention;

FIG. 3 is an explanatory diagram showing a circuit used for describing the concept of a phenomenon in which the resistance exhibited by the memory element right after a write operation is determined by a current flowing through the memory element right after the write operation;

FIG. 4 is an explanatory diagram showing a first circuit used for describing a typical storage device according to an embodiment of the present invention;

FIG. 5 is an explanatory diagram showing a second circuit used for describing a typical storage device according to an embodiment of the present invention;

FIG. 6 is an explanatory diagram showing a third circuit used for describing a typical storage device according to an embodiment of the present invention;

FIG. 7 is an explanatory diagram showing a fourth circuit used for describing a typical storage device according to an embodiment of the present invention;

FIG. 8 is a diagram showing a graph representing a relation between a voltage applied to the gate of a MOS transistor and a current flowing through the MOS transistor;

FIG. 9 is an explanatory diagram showing a read operation carried out on a memory element;

FIGS. 10A and 10B are explanatory diagrams showing models each used for describing a write-operation sequence according to an embodiment;

FIG. 11 is a diagram showing graphs each representing a relation between a difference in electric potential between the drain and source of a MOS transistor and a current flowing through the MOS transistor;

FIGS. 12A and 12B are diagrams showing graphs each representing a relation between the resistance of a memory element and a difference in electric potential between the drain and source of a MOS transistor; and

FIGS. 13A to 13C are explanatory diagrams showing graphs used for describing variations of the resistances exhibited by memory elements right after a write operation.

### DETAILED DESPCRIPTION OF THE PREFERRED EMBODIMENTS

The embodiments of the present invention are described by referring to diagrams as follows. It is to be noted that, in each of the embodiments, every variable-resistance storage element (which is also referred to as a memory element) is used in a memory cell serving as a component of a storage device.

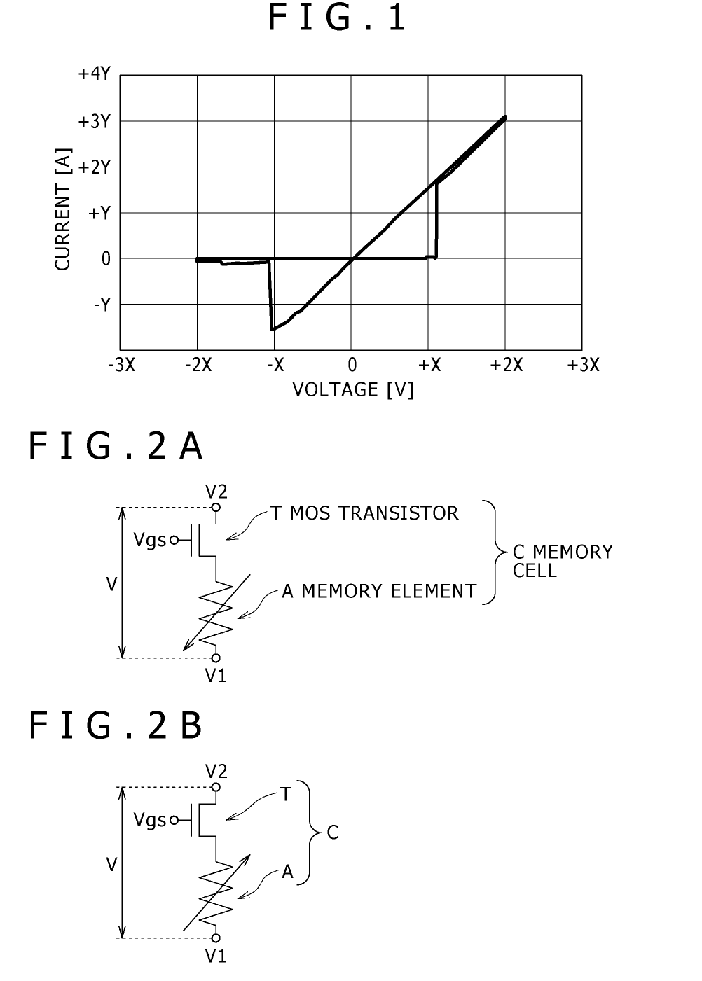

FIG. 1 is a diagram showing a graph representing an I-V relation between changes in current and changes in voltage for a memory element used in a typical storage device according to an embodiment of the present invention.

It is to be noted that the memory element having the I-V characteristic represented by the graph shown in FIG. 1 is a storage element having a typical configuration including first and second electrodes and a storage layer sandwiched by the first and second electrodes. The storage layer is typically an amorphous thin film such as a rare-earth oxide film. Typically, the first and second electrodes are provided as lower and upper electrodes respectively.

In an initial state of a memory element, the resistance is large so that a current hardly flows. A typical resistance value in the initial state is at least 1 MΩ. When a voltage of at least +1.1X [V] shown in FIG. 1 is applied to the memory element, however, the current increases abruptly and the resistor decreases to a value such as several KΩ. An example of +1.1X [V] is +0.5 V. Then, the characteristic of the memory element changes to the ohmic characteristic showing the current increasing proportionally to the applied voltage. That is to say, the ohmic characteristic is a constant-resistance characteristic. Even if the voltage is reset to 0 V afterward, the resistance continuously remains at a small value.

It is to be noted that the operation described above is referred to as a write operation and the state resulting from the write operation is called a conductive state. The voltage applied to carry out the write operation is known as a write voltage threshold value.

Next, when a voltage having a polarity opposite to the voltage applied to carry out the write operation is applied to the memory element, the current flowing through the memory element decreases abruptly, that is, the resistance increases abruptly to a large value equal to the initial-state resistance such as 1 MΩ or larger. Even if the voltage is reset to 0 V afterward, the resistance continuously remains at the large value. In FIG. 1, the opposite voltage is −1.1X [V] such as −0.5 V.

It is to be noted that the operation described above is referred to as an erase operation and the state resulting from the erase operation is called an insulating state. The voltage applied to carry out the erase operation is known as an erase voltage threshold value.

By applying a negative voltage to the memory element as described above, the resistance of the memory element can be reversely changed from several KΩ back to about 1 MΩ. In addition, if a voltage is not applied to the memory element, that is, if a voltage of 0 V is applied to the memory element, the memory element can be put in one of the two states, i.e., the conductive and insulating states. By associating these conductive and insulating states to data values of 1 and 0, 1-bit data can be stored in the memory element.

It is to be noted that, while the range −2X to +2X shown in FIG. 1 is the range of values of the voltage applied to the memory element, the applied voltage can be increased/decreased to a value beyond the range almost without changing the resistance of the memory element used in the typical storage device according to an embodiment of the present invention.

FIGS. 2A and 2B are explanatory diagrams showing circuits of a memory cell C used in the typical storage device according to an embodiment of the present invention. As shown in the figure, the memory cell C includes a memory element A and a MOS transistor T connected in series to the memory element A. In this circuit, the MOS transistor T serves not only as a switching element for selecting the memory element A being accessed, but also a load being borne by the memory element A.

In the configuration of the memory cell, the memory element A has an end connected to the MOS transistor T and an end on a side opposite to the end connected to the MOS transistor T. A terminal voltage V1 is applied to the end on the opposite side. By the same token, the MOS transistor T has an end connected to the memory element A and an end on a side opposite to the end connected to the memory element A. A terminal voltage V2 is applied to the end on the opposite side. Typically, the end to which the terminal voltage V2 is applied is the source of the MOS transistor T. A gate voltage Vgs is applied to the gate of the MOS transistor T.

By applying the voltages V1 and V2 to the opposite-side end of the memory element A and the opposite-side end of the MOS transistor T respectively in the memory cell as described above, an electric-potential difference V (=|V2-V1|) is applied to the ends of the memory cell.

Let us note that it is desirable to have a memory element exhibiting a write-operation resistance approximately equal to or greater than the on-resistance of the MOS transistor. This is because, if the resistance exhibited by the memory element at the beginning of an erase operation is small, the electric-potential difference applied to the ends of the memory cell appears between the ends of the MOS transistor so that the applied power is lost or is difficult to be used for changing the resistance of the memory element with a high degree of efficiency. It is also worth noting that, since the resistance exhibited by the memory element at the beginning of a write operation is large, the electric-potential difference applied to the ends of the memory cell appears between the terminals of the memory element so that this problem is not raised.

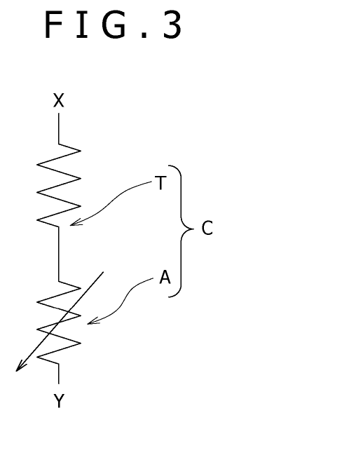

Results of experiments have revealed a phenomenon in which the resistance exhibited by the memory element of an embodiment of the present invention right after a write operation does not become equal to a univocal value unique to the memory element, but is determined by a current flowing through the memory element right after the write operation. FIG. 3 is an explanatory diagram showing a circuit used for describing the concept of a phenomenon in which the resistance exhibited by the memory element of an embodiment of the present invention right after a write operation is determined by a current flowing through the memory element. As shown in the figure, the circuit includes a memory element and a load resistor connected in series to the memory element. It is to be noted that the memory element is in an insulating state in which the resistance of the memory element has a value of at least 1 MΩ.

If a voltage equal to a write voltage threshold value of 0.5 V is applied between an end denoted by reference notation X and an end denoted by reference notation Y in FIG. 3 in a write direction, that is, in a direction from the end X to the end Y in the figure, the voltage of 0.5 V appears almost entirely between the ends of the memory element, causing the memory element to transit from the insulating state to a conductive state. The voltage of 0.5 V is applied almost entirely between the ends of the memory element because the resistance of the memory element is sufficiently greater than the resistance of the load resistor.

In addition, results of experiments have also indicated that the voltage appearing between the ends of the memory element right after a write operation stays at a fixed level such as approximately 0.2 V independently of the magnitude of the resistance of the load connected in series to the memory element. Thus:

[1] For a load resistance of 1 KΩ, a current of 0.3 mA (=(0.5 V−0.2 V)/1 KΩ) flows, setting the resistance of the memory element at 0.67 KΩ (=0.2 V/0.3 mA); and

[2] For a load resistance of 10 KΩ, a current of 0.03 mA (=(0.5 V−0.2 V)/10 KΩ) flows, setting the resistance of the memory element at 6.7 KΩ (=0.2 V/0.03 mA).

In this way, the resistance exhibited by the memory element right after a write operation is determined by the current flowing through the memory element. Once determined, the resistance exhibited by the memory element right after a write operation stays at a constant magnitude as long as voltage not exceeding the erase voltage threshold value is applied to the memory cell, that is, as long as voltage not exceeding the erase voltage threshold value is applied to the memory cell in a direction opposite to the direction of the write operation.

It is to be noted that, in the case of an erase operation, the phenomena described above are not observed. In the case of an erase operation, the insulating resistance changes to a value in the range several tens of KΩ to 1 MΩ or even a larger value without regard to the resistance obtained as a result of the write operation.

In dependence on the polarities of the memory element and the MOS transistor, there are two conceivable types of memory-cell configuration as shown in FIGS. 2A and 2B respectively.

It is to be noted that an arrow appended to the memory element as shown in FIGS. 2A and 2B indicates the polarity of the memory element. To put in detail, if a voltage is applied in the direction of the arrow, the memory element transits from an insulating state to a conductive state, that is, a write operation is carried out.

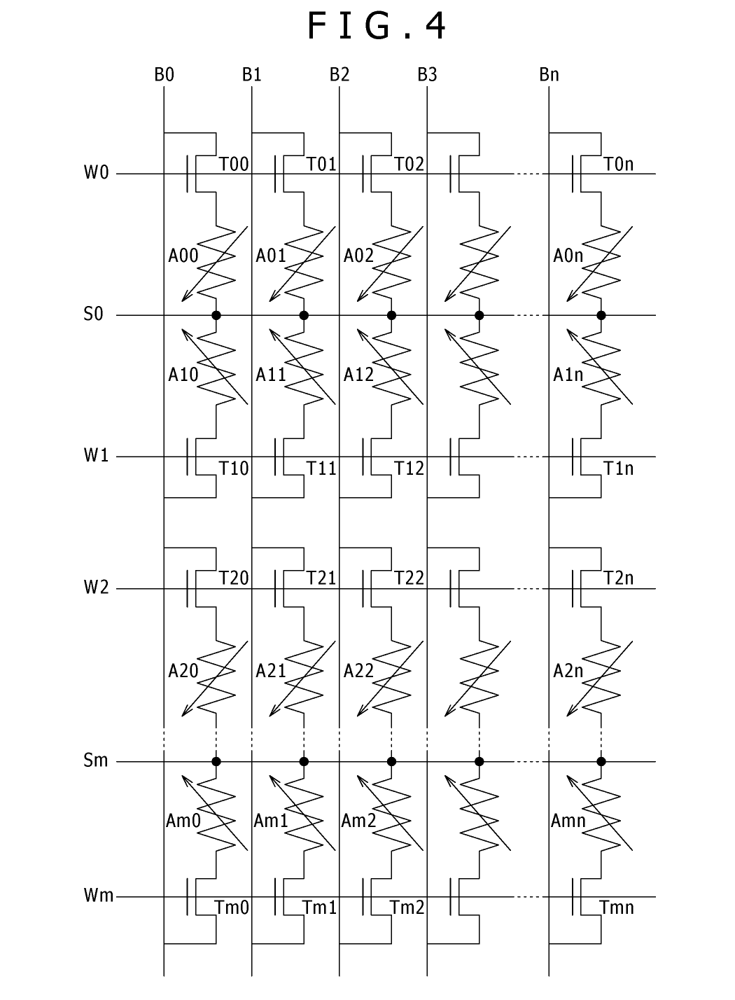

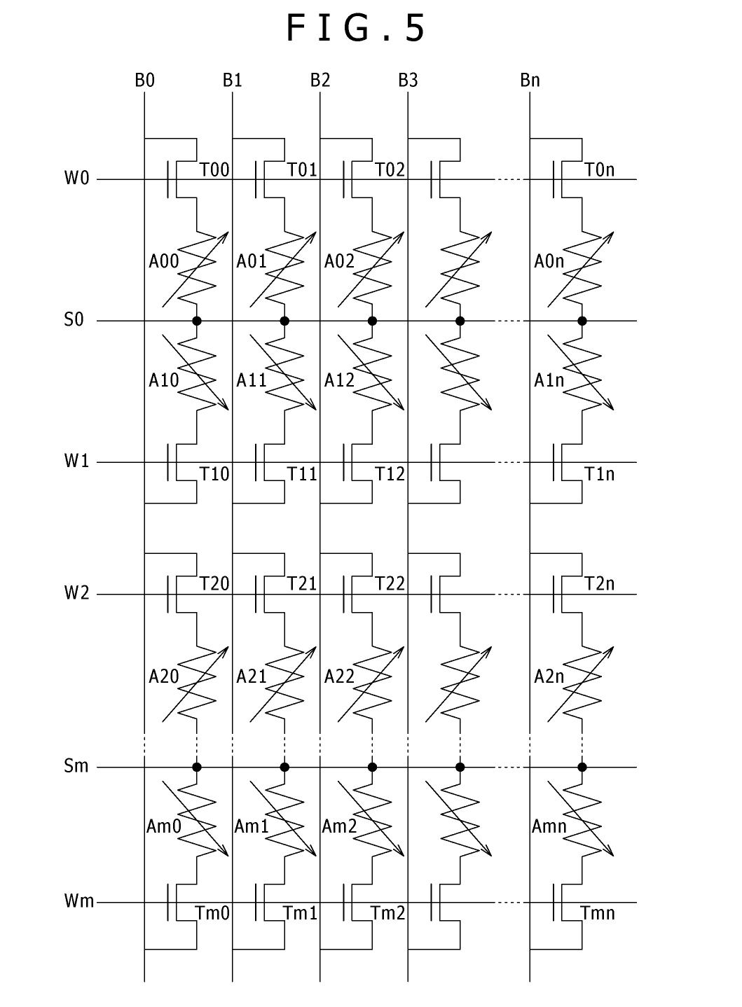

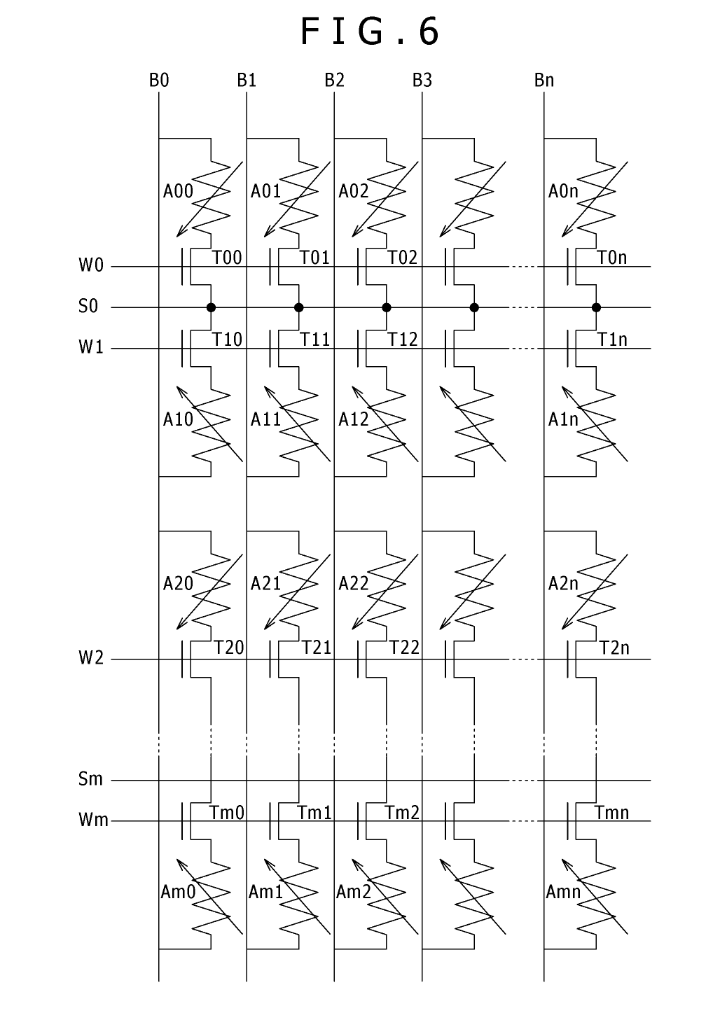

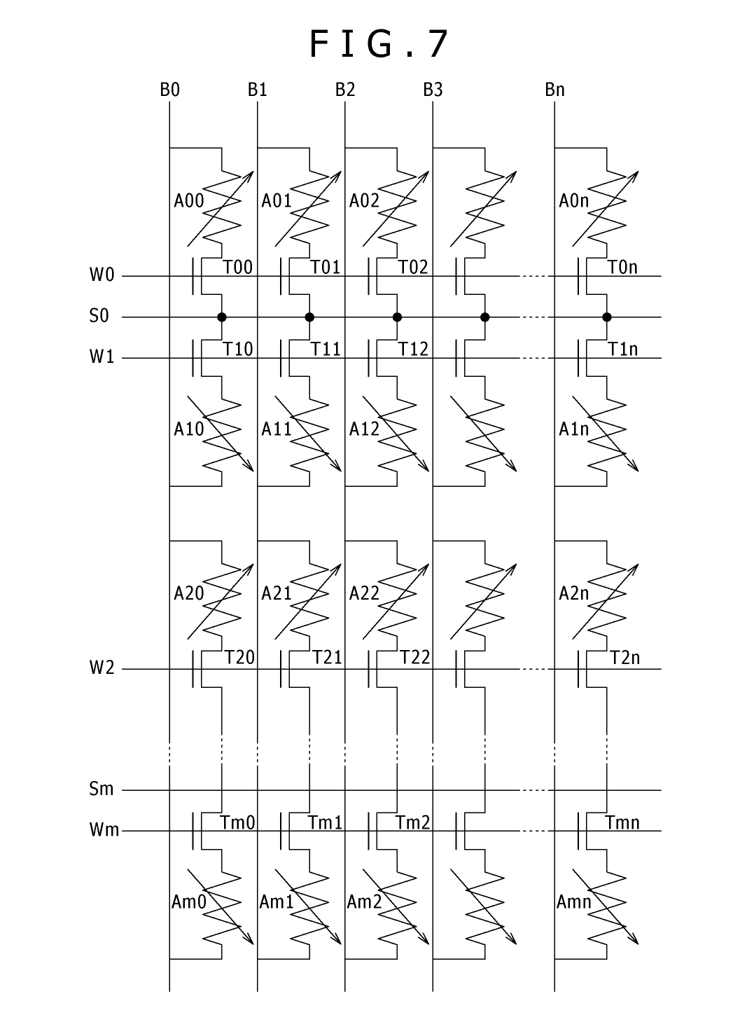

FIGS. 4 to 7 are each an explanatory diagram showing the circuit of a typical storage device according to an embodiment of the present invention. The circuits shown in the figures are each a memory array, which is a matrix of memory cells each shown in FIGS. 2A and 2B. It is to be noted that, in dependence on the polarity of the memory element as well as the layout of the MOS transistors and the memory elements, there are four conceivable types of memory-array configuration as shown in FIGS. 4, 5, 6, and 7 respectively.

Since a memory-array operation is carried out commonly to the memory arrays shown in FIGS. 4 to 7, the operation is explained by taking the memory array shown in FIG. 4 as an example.

The storage device shown in FIG. 4 includes memory cells laid out to form a matrix having (m+1) rows and (n+1) columns. As shown in FIGS. 2A and 2B, in each of the memory cells has a configuration in which one end of a memory element is connected to a MOS transistor T. In this embodiment, the end of the memory element is connected to the source of the MOS transistor T.

The gate of each of the MOS transistors T00 to Tmn is connected to a word line W, that is, one of word lines W0 to Wm. The other end of the MOS transistor T is connected to a bit line B, that is, one of bit lines BO to Bn. In this embodiment, the other end of the MOS transistor T is the drain of the MOS transistor T. The other end of the memory element is connected to a source line S, that is, one of source lines S0 to Sm.

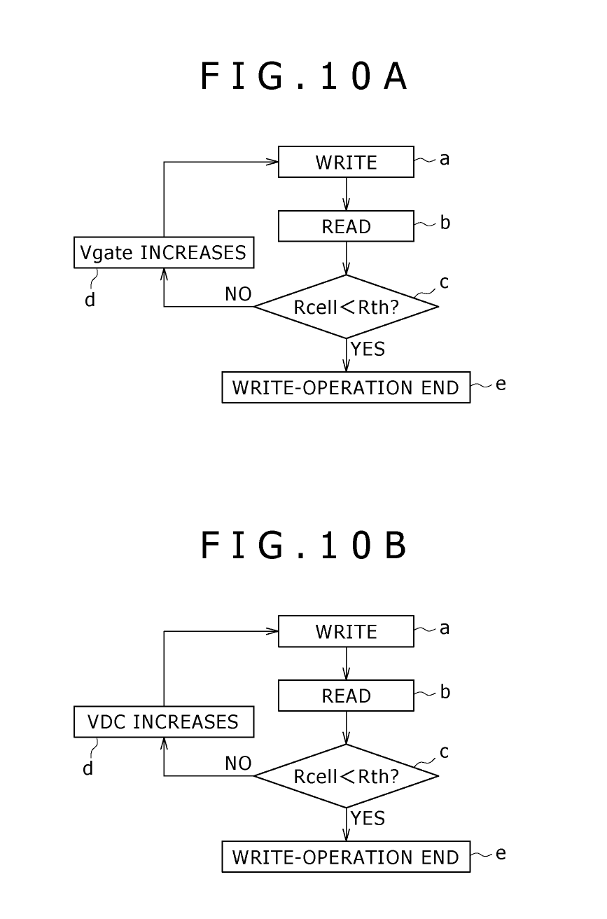

The following description explains embodiments each implementing a write-operation sequence of the storage device provided by an embodiment of the present invention for the following cases:

[1] A voltage applied to the gate of the MOS transistor is controlled in accordance with a flowchart shown in FIG. 10A; and

[2] A voltage applied between the drain and source of the MOS transistor is controlled in accordance with a flowchart shown in FIG. 10B.

It is to be noted that the following description assumes that the write voltage threshold value of the memory element is 0.5 V.

[1] A Voltage Applied to the Gate of the MOS Transistor is Controlled in Accordance with a First Embodiment

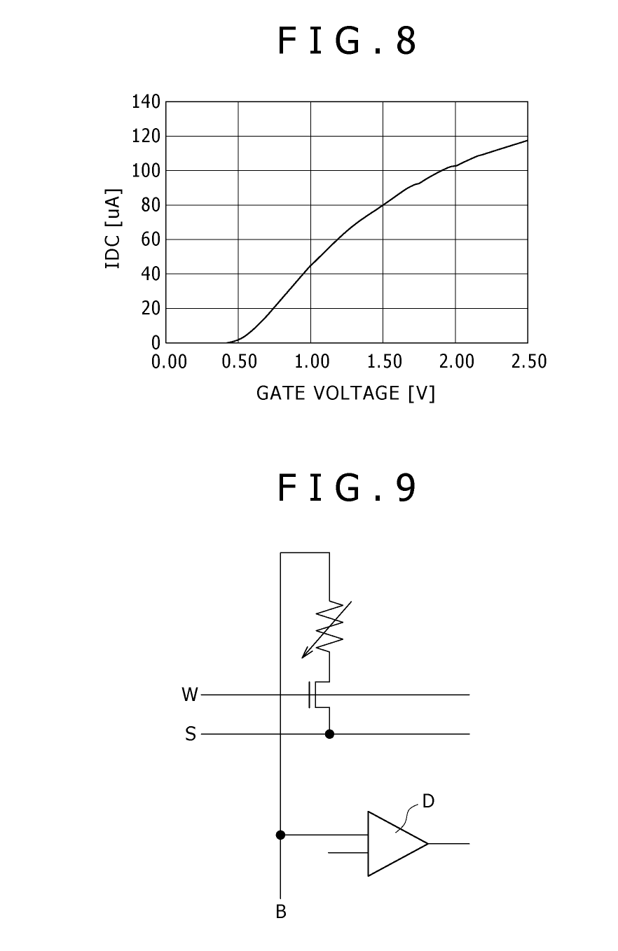

The first embodiment implements a storage device including memory cells each having a configuration having a MOS transistor and a memory element connected in series to the MOS transistor. The memory element is designed so as to exhibit a difference of 0.2 V in electric potential between the ends of the memory element right after a write operation. The MOS transistor is designed so as to exhibit a relation shown in FIG. 8 right after a write operation by applying a voltage of 0.5 V between the drain and source of the MOS transistor as a relation between Vgate representing a voltage appearing at the gate of the MOS transistor and IDC representing a current flowing through the MOS transistor. That is to say, the relation shown in FIG. 8 as a relation between Vgate and IDC is a relation obtained with a voltage of 0.3 V applied between the drain and source of the MOS transistor on the assumption that a voltage of 0.2 V appears between the ends of the memory element.

As is obvious from the relation shown in FIG. 8 as a relation between Vgate representing a voltage appearing at the gate of the MOS transistor and IDC representing a current flowing through the MOS transistor, if the voltage applied to the gate of the MOS transistor is increased, the current flowing through the MOS transistor also rises.

In addition, in order to further reduce the resistance of the memory element by carrying out a rewrite operation, it is necessary to flow a current greater than the current of the preceding write operation in the rewrite operation. That is to say, as is shown in FIG. 8 as a relation between the voltage at the gate of the MOS transistor and the current flowing through the MOS transistor, in order to carry out a rewrite operation, it is necessary to apply a voltage higher than the voltage, which appeared at the gate of the MOS transistor in the preceding write operation, to the gate of the MOS transistor in the rewrite operation.

On the basis of the point described above, as an example, the following description explains a case in which a voltage of 0.5 V is applied between the ends of the memory cell including the drain and source of the MOS transistor in the first embodiment in an attempt to set the resistance of the memory element to be 6.0 KΩ.

In the first embodiment, first of all, a voltage of 0.87 V is applied to the gate of the MOS transistor in an initial state to carry out a first write operation at a step ‘a’ of a flowchart shown in FIG. 10A.

In this case, the voltage applied to the gate of the MOS transistor in an initial state to carry out a first write operation can have any magnitude as long as the magnitude is large enough for setting the resistance exhibited by the memory element right after the first write operation at a value higher than the set value. That is to say, the magnitude of the voltage applied to the gate of the MOS transistor in an initial state to carry out a first write operation is not necessarily 0.87 V.

Then, at the next step ‘b’ of the flowchart shown in FIG. 10A, a first read operation is carried out to measure the resistance exhibited by the memory element right after the first write operation.

To put it concretely, since the relation between the resistance of the memory element and the current flowing through the bit line satisfies Eq. A given below, the resistance of the memory element can be measured by detecting the current flowing through the bit line by using a sense amplifier D connected to the bit line as shown in FIG. 9. Let us assume that, as a result of the measurement, the resistance exhibited by the memory element right after the first write operation is found to be 6.22 KΩ.
Resistance of memory element=0.2 V/(current flowing through bit line) (A)

Then, at the next step ‘c’ of the flowchart shown in FIG. 10A, the resistance Rcell obtained as a result of the measurement carried out by performing the first read operation is compared with the set value Rth. In this case, since the relation Rcell (=6.22 KΩ)>Rth (=6.0 KΩ) holds true, the flow of the write-operation sequence goes on to a step ‘d’ of the flowchart shown in FIG. 10A. At the step ‘d’, the voltage applied to the gate of the MOS transistor is increased by 0.01 V. That is to say, this time, a voltage of 0.88 V is applied to the gate of the MOS transistor. Then, the flow of the write-operation sequence goes back to the step ‘a’ of the flowchart shown in FIG. 10A. At the step ‘a’, this time, a second write operation is carried out.

Then, at the next step ‘b’ of the flowchart shown in FIG. 10A, a second read operation is carried out to measure the resistance exhibited by the memory element right after the second write operation. Let us assume that, as a result of the measurement, the resistance exhibited by the memory element right after the second write operation is found to be 6.04 KΩ.

Then, at the next step ‘c’ of the flowchart shown in FIG. 10A, the resistance Rcell obtained as a result of the measurement carried out by performing the second read operation is compared with the set value Rth. In this case, since the relation Rcell (=6.04 KΩ)>Rth (=6.0 KΩ) still holds true, the flow of the write-operation sequence goes on to the step ‘d’ of the flowchart shown in FIG. 10A. At the step ‘d’, the voltage applied to the gate of the MOS transistor is increased by 0.01 V. That is to say, this time, a voltage of 0.89 V is applied to the gate of the MOS transistor. Then, the flow of the write-operation sequence goes back to the step ‘a’ of the flowchart shown in FIG. 10A. At the step ‘a’, this time, a third write operation is carried out.

Then, at the next step ‘b’ of the flowchart shown in FIG. 10A, a third read operation is carried out to measure the resistance exhibited by the memory element right after the third write operation. Let us assume that, as a result of the measurement, the resistance exhibited by the memory element right after the third write operation is found to be 5.87 KΩ.

Then, at the next step ‘c’ of the flowchart shown in FIG. 10A, the resistance Rcell obtained as a result of the measurement carried out by performing the third read operation is compared with the set value Rth. In this case, since the relation Rcell (=5.87 KΩ)<Rth (=6.0 KΩ) holds true, the flow of the write-operation sequence goes on to a step ‘e’ of the flowchart shown in FIG. 10A. At the step ‘e’, the execution of the write-operation sequence is ended.

By executing the write-operation sequence as described above, the resistance of the memory element is set at 5.87 KΩ.

[2] A Voltage Applied Between the Drain and Source of the MOS Transistor is Controlled in Accordance with a Second Embodiment

In the first embodiment described above, the voltage applied to the gate of the MOS transistor is controlled in order to adjust the current flowing through the memory cell. In the case of the second embodiment, on the other hand, a voltage applied between the drain and source of the MOS transistor is controlled in order to adjust the current flowing through the memory cell.

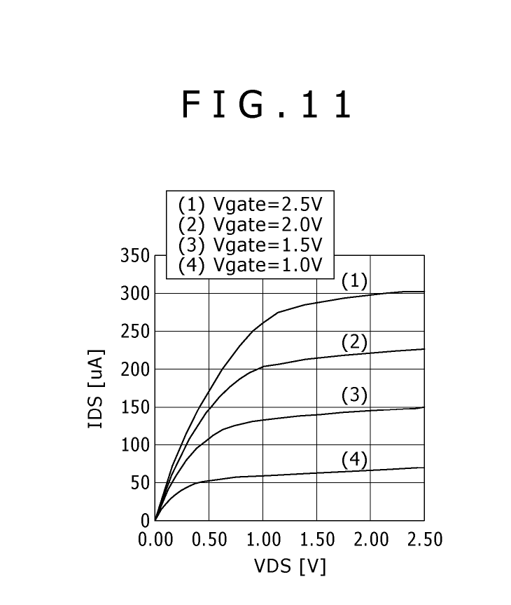

The second embodiment implements a storage device including memory cells each having a configuration having a memory element and a MOS transistor connected in series to the memory element. The memory element is designed so as to have a difference of 0.2 V in electric potential between the ends thereof right after a write operation. On the other hand, the MOS transistor is designed so as to have relations each shown in FIG. 11 as a relation between the electric-potential difference VDS between the drain and source thereof and the current IDS flowing thereto.

As is obvious from the relations each shown in FIG. 11 as a relation between the electric-potential difference VDS between the drain and source thereof and the current IDS flowing thereto, with the voltage of the gate of the MOS transistor kept at a constant level, the current flowing through the MOS transistor increases as the voltage applied between the drain and source of the MOS transistor is raised.

In addition, if the difference in electric potential between the ends of the memory element is kept at a fixed level of 0.2 V, the voltage applied between the drain and source of the MOS transistor can be expressed by Eq. B given below.

In addition, in order to reduce the resistance of the memory element by carrying out a rewrite operation, it is necessary to flow a current greater than the current of the preceding write operation in the rewrite operation. That is to say, as is obvious from Eq. B and the relations each shown in FIG. 11 as a relation between the electric-potential difference VDS between the drain and source thereof and the current IDS flowing thereto, in the rewrite operation, it is necessary to apply a voltage between the drain and source of the MOS transistor at a level higher than the voltage applied between the drain and source of the MOS transistor in the preceding write operation.
Difference in electric potential between drain and source of MOS transistor=(Difference in electric potential between bit and source lines)−0.2 V (B)

On the basis of the point described above, as an example, the following description explains a case in which the resistance of the memory element is set to a predetermined set value by applying a constant voltage to the gate of the MOS transistor.

In the second embodiment, first of all, a predetermined voltage is applied between the drain and source of the MOS transistor in an initial state to carry out a first write operation at a step ‘a’ of a flowchart shown in FIG. 10B. Then, at the next step ‘b’ of the flowchart shown in FIG. 10B, a first read operation is carried out to measure the resistance exhibited by the memory element right after the first write operation. It is to be noted that the concrete method to carry out a read operation is the same as the first embodiment.

Then, at the next step ‘c’ of the flowchart shown in FIG. 10B, the resistance Rcell obtained as a result of the measurement carried out by performing the first read operation is compared with the set value Rth. The following two cases are conceivable:

(1) If the result of the comparison of Rcell with Rth indicates that the relation Rcell>Rth holds true, the flow of the write-operation sequence goes on to a step ‘d’ of the flowchart shown in FIG. 10B. At the step ‘d’, the voltage applied between the drain and source of the MOS transistor is increased in order to carry out another rewrite operation. After the other rewrite operation is carried out, the resistance Rcell obtained as a result of a measurement carried out by performing a read operation is again compared with the set value Rth; and

(2) If the result of the comparison of Rcell with Rth indicates that the relation Rcell<Rth holds true, on the other hand, the flow of the write-operation sequence goes on to a step ‘e’ of the flowchart shown in FIG. 10B. At the step ‘e’, the execution of the write-operation sequence is ended.

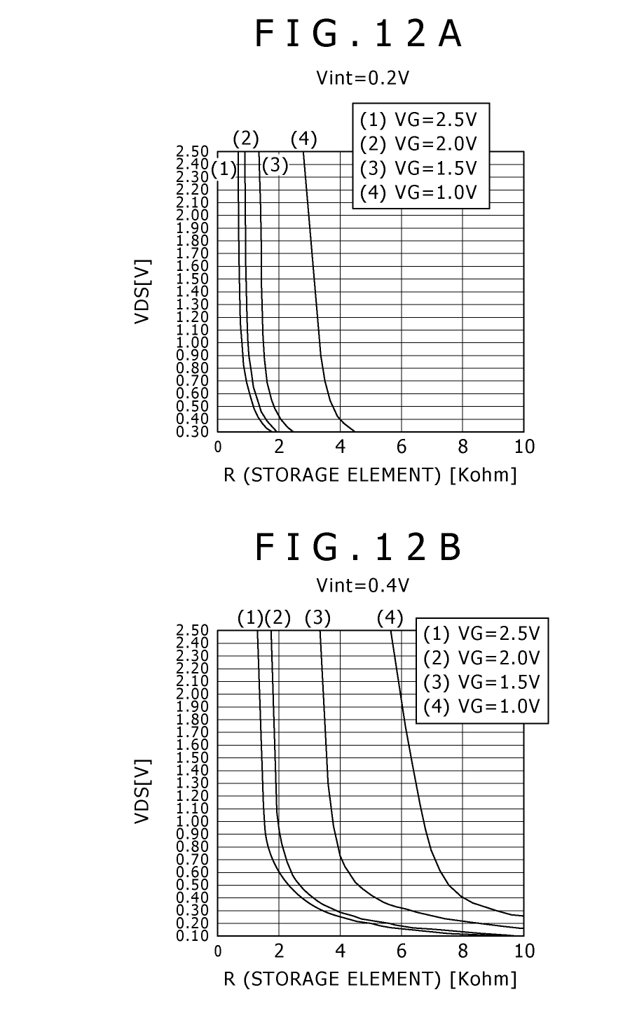

It is to be noted that FIG. 12A is a diagram showing relations between the resistance R (storage element) and the electric-potential difference between the drain and source of the MOS transistor. The resistance R is the memory element designed so as to exhibit an electric-potential difference Vint of 0.2 V appearing between the ends of the memory element right after a write operation and. On the other hand, FIG. 12B is a diagram showing relations between the resistance R (storage element) and the electric-potential difference between the drain and source of the MOS transistor. The resistance R is the memory element designed so as to exhibit an electric-potential difference Vint of 0.4 V appearing between the ends of the memory element right after a write operation.

As is obvious from the relations shown in FIGS. 12A and 12B as relations between the resistance R (storage element) of the memory element and the difference in electric potential between the drain and source of the MOS transistor, the larger the electric-potential difference Vint appearing between the ends of the memory element right after a write operation, the more sufficient the resistance change ratio.

As described above, in the case of the first embodiment, during the write-operation sequence, the resistance of the memory element is detected and write operations are carried out by adjusting the voltage applied to the gate of the MOS transistor. In the case of the second embodiment, on the other hand, during the write-operation sequence, the resistance of the memory element is detected and write operations are carried out by adjusting the voltage applied between the drain and source of the MOS transistor. Thus, in either case, the discrepancy between the resistance of the memory element and the set value can be reduced to improve controllability of the resistance of the memory element.

To put it concretely, even if the electric-potential difference appearing between the ends of the memory element right after a write operation is shifted by +5% from the ideal value of 0.2 V, by carrying out write operations in accordance with the write-operation sequence represented by the flowchart shown in FIG. 10A, the resistance of the memory element can be set at 5.92 KΩ. It is to be noted that the voltage applied to the gate of the MOS transistor at that time is 0.91 V.

In addition, even if the electric-potential difference appearing between the ends of the memory element right after a write operation is shifted by −5% from the ideal value of 0.2 V, by carrying out write operations in accordance with the write-operation sequence represented by the flowchart shown in FIG. 10A, the resistance of the memory element can be set at 5.83 KΩ. It is to be noted that the voltage applied to the gate of the MOS transistor at that time is 0.87 V.

That is to say, even if there are variations of approximately ±5% relative to the ideal value of 0.2 V among the values of the electric-potential difference appearing between the ends of the memory element right after a write operation, by carrying out write operations in accordance with the write-operation sequence represented by the flowchart shown in FIG. 10A, the resistance of the memory element can be set at a value in the range 5.83 KΩ to 5.92 KΩ.

In order to reduce variations of the resistance existing between the ends of the memory element right after a write operation, in the case of the first embodiment, during the write-operation sequence, the resistance of the memory element is detected and write operations are carried out by adjusting the voltage applied to the gate of the MOS transistor. In the case of the second embodiment, during the write-operation sequence, the resistance of the memory element is detected and write operations are carried out by adjusting the voltage applied between the drain and source of the MOS transistor.

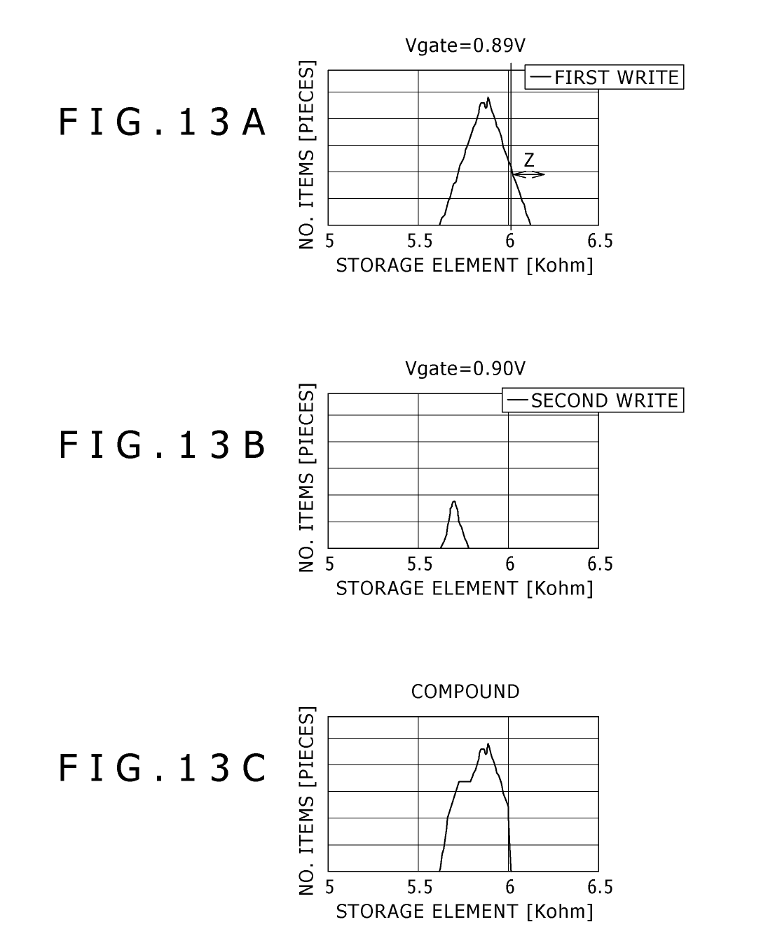

To put it concretely, let us assume that write operations are carried out on M memory elements each employed in a memory cell under a condition that the set value is 6.0 KΩ and the gate voltage is 0.89 V. Let us also assume that, in this case, the electric-potential difference appearing between the ends of the memory element right after a write operation is shifted by ±5% from the ideal value of 0.2 V as is the cases described above. On these assumptions, the resistance exhibited by the memory element right after a write operation is set at a value in the range 5.50 KΩ to 6.25 KΩ. FIG. 13A is a diagram showing a distribution of variations of the resistance set at values in the range as the resistance of the memory element.

It is to be noted that the variations represented by the distribution shown in FIG. 13A as a distribution of variations of the resistance exhibited by the memory element corresponds to variations of the resistance exhibited by the memory element as a result of the write-operation sequence in related art. In accordance with the write-operation sequence in related art, write operations are carried out without adjusting the voltage of the MOS transistor during the sequence.

If a rewrite operation is carried out on a memory cell, in which the memory element thereof exhibits a resistance Rcell greater than the set value Rth (Rcell>Rth) in accordance with execution of the write-operation sequence shown in FIG. 10A, by applying a voltage of 0.90 V to the gate of the MOS transistor, the memory element exhibits a resistance having a value in the range 5.35 KΩ to 6.08 KΩ right after the rewrite operation. The memory cell, in which the memory element thereof exhibits a resistance Rcell still greater than the set value Rth (Rcell>Rth), is a memory cell with the memory element thereof denoted by reference notation Z in FIG. 13A. Among memory elements each exhibiting a resistance having a value in the range 5.35 KΩ to 6.08 KΩ, variations in resistance are shown in FIG. 13B.

If the variation distribution shown in FIG. 13A as a distribution of variations of the resistances exhibited by the memory elements (except memory elements denoted by reference notation Z in the figure) right after a write operation is superposed on the variation distribution shown in FIG. 13B as a distribution of variations of the resistances exhibited by the memory elements right after a rewrite operation, a variation distribution shown in FIG. 13C is obtained. The variation distribution shown in FIG. 13C is a distribution of variations of the resistances exhibited by the memory elements as a result of execution of the write-operation sequence shown in FIG. 10A. As is obvious from FIG. 13C, the range of the distribution of variations among the resistances exhibited by the memory elements becomes narrower.

By controlling the voltage applied to the memory cell or the current flowing through the memory cell during a write operation, the resistance exhibited by the memory element of the memory cell right after the write operation can be set at a plurality of levels different from each other. There has been proposed a technology in which three or more different values of information can be stored in a memory element employed in a memory cell by associating a plurality of levels, which correspond to states of small and large resistances exhibited after the write operation, with the different values of information. For more information on such a technology, refer to Japanese Patent Application No. 2004-124543.

In order to implement the technology described above, N set values Rth, where N≧2, in a settable range are searched for in the case of both the first and second embodiments. By having N set values Rth, the values of the resistance exhibited right after a write operation can be separated from each other. That is to say, (N+1) different values of information can be stored in the memory element. The (N+1) different values of information represent N different write states and an erase state.

In addition, the embodiments allow the resistance of the memory element to be controlled without executing an erase-operation sequence so that a write operation can be corrected in a short period of time.

That is to say, in the write-operation correction in related art, when a write operation ends in a failure, an erase operation is necessary. In accordance with the embodiments, on the other hand, read operations are each carried out right after a write operation in a write-operation sequence in order to adjust the resistance of the memory element. Thus, a write operation can be corrected in a short period of time.

It should be understood that those skilled in the art that various modifications, combinations, sub-combinations, and alternations may occur depending on design requirements and other factors insofar as they are within the scope of the appended claims or the equivalents thereof.

What is claimed is:

1. A storage device comprising:
a storage element having a characteristic exhibiting a resistance changing from a large value to a small value due to application of an electrical signal at least equal to a first threshold signal but changing from a small value to a large value due to application of an electrical signal at least equal to a second threshold signal having a polarity opposite to the polarity of said first threshold signal;
a circuit element connected in series to said storage element; and
write control means configured to carry out a first write operation in an attempt to set said storage element to a higher resistance than a set value determined in advance, detect a resistance exhibited by said storage element after an n-th write operation, where n≧1, compare said detected resistance with said set value, and carry out a (n+1)-th write operation if a result of comparison indicates that said resistance exhibited by said storage element after said n-th write operation is still greater than said set value.

2. The storage device according to claim 1 wherein
said circuit element is a unipolar transistor; and
a voltage applied by said write control means to the gate of said unipolar transistor in said (n+1)-th write operation is higher than a voltage applied by said write control means to said gate of said unipolar transistor in said n-th write operation.

3. The storage device according to claim 1 wherein
said circuit element is a unipolar transistor; and
a voltage applied by said write control means as a voltage appearing between the drain and source of said unipolar transistor in said (n+1)-th write operation is higher than a voltage applied by said write control means as a voltage appearing between said drain and source of said unipolar transistor in said n-th write operation.

4. The storage device according to claim 1 wherein
said storage element includes a first electrode, a second electrode, and a storage layer sandwiched by said first and second electrodes;
if an electrical signal at least equal to a first threshold signal is applied between said first and second electrodes, the resistance of said storage element changes from a large value to a small value; and
if an electrical signal at least equal to a second threshold signal is applied between said first and second electrodes, said resistance of said storage element changes from a small value to a large value.

5. A semiconductor device employing a storage device comprising:
a storage element having a characteristic exhibiting a resistance changing from a large value to a small value due to application of an electrical signal at least equal to a first threshold signal but changing from a small value to a large value due to application of an electrical signal at least equal to a second threshold signal having a polarity opposite to the polarity of said first threshold signal;
a circuit element connected in series to said storage element; and
write control means configured to carry out a first write operation in an attempt to set said storage element to a higher resistance than a set value determined in advance, detect a resistance exhibited by said storage element after an n-th write operation, where n≧1, compare said detected resistance with said set value, and carry out a (n+1)-th write operation if a result of comparison indicates that said resistance exhibited by said storage element after said n-th write operation is still greater than said set value.
